(19) United States
(12) Patent Application Publication
(10) Pub. No.: US 2001/0002061 A1
(43) Pub. Date: May 31, 2001

(54) Self-aligned in situ doped plug emitter

(76) Inventor: F. Scott Johnson, Garland, TX (US)

Correspondence Address: TEXAS INSTRUMENTS INCORPORATED, P O BOX 655474, M/S 3999, DALLAS, TX, 75265

(21) Appl. No.: 09/737,638

(22) Filed: Dec. 14, 2000

Related U.S. Application Data
(62) Division of application No. 09/167,909, filed on Oct. 7, 1998.
(60) Provisional application No. 60/060,259, filed on Sep. 29, 1997.

(51) Int. Cl. H01L 21/331; H01L 27/082; H01L 27/102; H01L 29/70; H01L 31/11

(52) U.S. Cl. 257/565; 257/591; 438/345; 438/366

(57) ABSTRACT

An emitter contact structure including a silicon substrate having a collector region, a base region within the collector region, and an emitter region within the base region. A base polysilicon layer positioned on the silicon substrate in contact with the base region and defining an aperture, with side walls, exposing the base and emitter regions of the silicon substrate. A spacer extending upwardly from the silicon substrate and formed to cover the side walls, the spacer covering the base region and partially covering the emitter region. An emitter polysilicon layer positioned entirely within the aperture in engagement with the emitter region, the spacer and the substrate without overlapping the base polysilicon layer.

### FIELD OF THE INVENTION

This invention relates to semiconductor products and related processing, and more particularly to the formation of the emitter contact structure, and the process for making the same.

### BACKGROUND OF THE INVENTION

BiCMOS based integrated circuits combine bipolar and CMOS technologies on the same integrated circuit device. This requires the actual processing of the device during fabrication to be performed in a manner that satisfies the unique structural characteristics of both the bipolar and CMOS features. While existing fabrication processes are functional, several individual fabrication methods and the resulting structures could be improved. One of these is the formation of the emitter contact structure in a bipolar junction transistor.

Presently known processes requiring polysilicon deposition into emitter contacts result in narrow emitter effects, contact resistance problems and unwanted parasitic spacers (resulting from the LDD process for the MOS devices). By depositing a relatively thick polysilicon layer on a device topology designed to fill or plug the emitter contact, these problems are avoided, and the advantages of reduced topography are obtained.

Typical polysilicon deposition in self-aligned emitter contact structures result in topography over the emitter region that creates problems with emitter junction formation as well as obtaining the desired low resistance contacts in BiCMOS technologies. The polysilicon layer deposited into the emitter structure over the sidewall spacers can block a significant portion of the subsequent Arsenic (As) emitter implant, resulting in narrow emitter effects. Narrow emitter effects are a variation in gain and frequency performance based on emitter sizing. While narrow emitter effects can be corrected by in situ doping or the formation of deeper emitter junctions, these corrective efforts have drawbacks. In situ doping is hampered by the existence of the parasitic spacers. Deeper emitter junctions cause slower device operation. Thus a significant problem remains.

In BiCMOS processes, the formation of the low doped drain (LDD), spacer and source/drain (S/D) junctions must follow the emitter formation (including the emitter anneal) due to thermal budget constraints. When a spacer is formed in the CMOS devices, a larger, taller parasitic spacer is formed within the emitter contact structure of the self-aligned bipolar junction transistor. This parasitic spacer blocks silicide formation and limits the area available for contact by the tungsten plug. Even with the addition of extra patterning and etch steps, this spacer is difficult to remove.

It is with the foregoing problems in mind that the instant invention was developed.

### SUMMARY OF THE INVENTION

The present invention concerns an emitter contact structure, and method for making, for a bipolar junction transistor. The emitter contact structure includes a silicon substrate having a collector region, a base region within the collector region, and an emitter region within the base region. A base polysilicon layer is positioned on the silicon substrate in contact with the base region and defines an aperture, with side walls, exposing the base and emitter regions of the silicon substrate. A spacer extends upwardly from the silicon substrate and is formed to cover the side walls, the spacer covering the base region and partially covering the emitter region. An emitter polysilicon layer is positioned entirely within the aperture in engagement with the emitter region, the spacer and the substrate.

In another embodiment, the spacer defines a top edge and the emitter polysilicon defines a top surface, and the top surface of the emitter polysilicon is in alignment with the top edge of the spacer.

In yet another embodiment, the spacer defines a top edge and the emitter polysilicon defines a top surface, and the top surface of the emitter polysilicon is below the top edge of the spacer.

The method of the present invention for forming an emitter contact for a bipolar junction transistor includes the steps of providing a silicon substrate having a collector region, a base region within the collector region, and an emitter region within the base region, depositing a base polysilicon layer on the silicon substrate in contact with the base region, and defining an aperture with side walls exposing the base and emitter regions of the silicon substrate. Then, a spacer is formed which extends upwardly from the silicon substrate and covers the side walls, the spacer also covering the base region and partially covering the emitter region. An emitter polysilicon layer is then positioned within the aperture in engagement with the emitter region, the spacer and the substrate.

It is a primary object of the present invention to provide an emitter contact for a bipolar junction transmitter that provides adequate connection to the emitter region while reducing topographical variation over the structure.

Another object of the present invention is to provide an emitter contact for a bipolar junction transmitter that provides self-aligned emitter polysilicon engagement with the emitter region.

Another object of the present invention is to eliminate the overlap emitter polysilicon on the base polysilicon to maximize the area available for silicide formation.

The foregoing and other features, utilities and advantages of the invention will be apparent from the following more particular description of a preferred embodiment of the invention as illustrated in the accompanying drawings.

### BRIEF DESCRIPTION OF THE DRAWINGS

FIG. 1 is a representational section view of a contact to an emitter region in a bipolar junction transistor.

FIG. 2 is a representational section view of a contact to an emitter region filled with a layer of polysilicon.

FIG. 3 is a representational section view of a contact to an emitter region during an etching step.

FIG. 4 is a representational section view of a contact to an emitter region after being filled by a layer of polysilicon and etched back to reduce the profile.

### DETAILED DESCRIPTION OF THE PREFERRED EMBODIMENT

An emitter polysilicon plug is described, and reduces narrow emitter effects, prevents unwanted spacers and improves silicide and contact formation in BiCMOS processes. In the fabrication of the inventive structure, known or available processing steps, such as deposition and etching techniques, can be used for the individual steps.

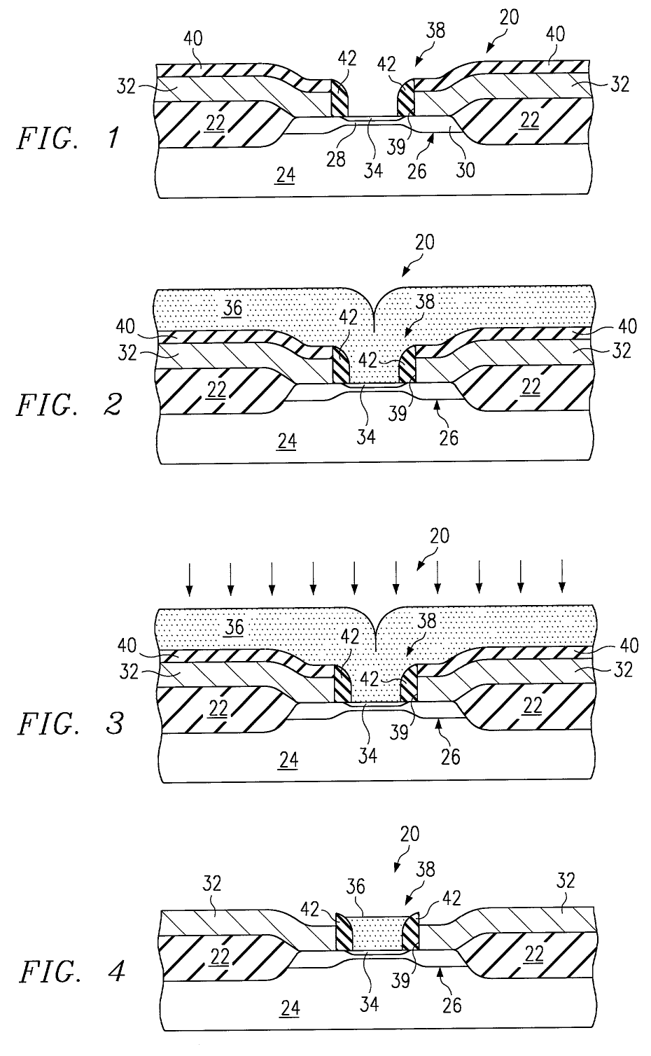

Bipolar junction transistors (BJTs) are commonly used in semiconductor devices especially for high speed operation and large drive current applications. A standard double polysilicon BJT 20 is shown in FIG. 1. The area for the BJT is isolated by field oxides 22. The collector 24 is a lightly doped epitaxial layer of one conductivity type and the base region 26 is formed by doped regions of the opposite conductivity type. The doped region 28 is called the intrinsic base region, and doped region 30 is called the extrinsic base region. The extrinsic base region 30 provides an area for externally connecting to the base region 26. The base electrode 32 is a first layer of doped polysilicon. The emitter region 34 is a doped region of the same conductivity type as the collector region 24, and is located within the intrinsic base region 28. The emitter electrode 36 (FIGS. 2-4) is a second layer of doped polysilicon, and is subsequently deposited, as explained below, into the emitter contact 38. The emitter contact 38 is an aperture formed through the base polysilicon 32 and the oxide 40 layers. The aperture defines sidewalls 39, and exposes a portion of the base region and the emitter region.

Oxide layer 40, or interpolysilicon dielectric (IPD), and base-emitter spacers 42 isolate the emitter electrode 36 from the base electrode 32. The sidewall spacers 42 are formed by the conformal deposition of silicon nitride, or other suitable material, into the emitter contact aperture 38 and then performing an anisotropic etch-back, as is well known. Double polysilicon BJTs 20 have the advantage of lower base resistance and reduced extrinsic capacitances over single polysilicon BJTs.

In the structure shown in FIG. 1, the base polysilicon layer 32 is approximately 2000 Å thick, and the oxide layer 40 deposited on top of the base polysilicon 32 is approximately 3000 Å thick. The emitter contact 38 has a major dimension of between approximately 0.6 and 1.2 microns. After the formation of the spacers 42, the major dimension of the emitter contact 38 is between approximately 0.3 and 0.6 microns.

The in situ doped emitter polysilicon 32 (second layer of polysilicon) is then deposited, as shown in FIG. 2, into the emitter contact 38 at such a thickness that the emitter contact 38 is completely filled. The emitter polysilicon 36 provides excellent conformal coverage in the emitter contact and completely fills the emitter contact while minimizing the formation of voids. Depending on the major dimension and aspect ratio of the emitter contact 38, the doped emitter polysilicon can be between 2000 and 4000 Å thick.

Narrow emitter effects are reduced or eliminated in this structure by the replacement of ion implantation by in situ doping of the emitter region 34 by the emitter polysilicon 36. An emitter polysilicon in situ doped with desired dopant material, such as arsenic or phosphorous, is sufficient to form the emitter region 34 within the base region 28. The formation of parasitic spacers due to the LDD process step is eliminated due to the fact t hat the emitter polysilicon plug covers up the features on which the parasitic spacers form.

A possible increase in the emitter resistivity due to the thicker polysilicon may occur in this structure. However, this can be offset by increasing the doping of the emitter polysilicon 36 over that of ion implantation, and by using a rapid thermal anneal (RTA) after deposition of the emitter polysilicon. A preferred doping level and RTA process includes in situ doping the emitter polysilicon up to 1E21 atoms per cubic centimeter (cm), followed by an RTA at 1050C for 10 seconds. This combination of steps will maintain shallow doping profiles in the single crystal portion of the emitter region 34 while providing the oxide breakup at the poly-crystal silicon interface, and create the activation necessary for low resistance. In addition, this increased in situ doping and subsequent RTA does not adversely affect the other performance characteristics of the BJT.

In the present invention a self-aligned polysilicon emitter is used to form an improved BJT structure by depositing in situ doped polysilicon and subsequently etching-back the emitter polysilicon 36, as described below. Narrow emitter effects are eliminated by in situ doping by the emitter polysilicon (which replaces known emitter implantation), while silicide and contact resistance problems in the emitter contact (due to unwanted parasitic sidewall spacer formation) are reduced or eliminated by using a thicker polysilicon deposition to “plug” the emitter contact apertures.

As shown in FIGS. 3 and 4, a planarizing emitter polysilicon etch-back is performed after the emitter polysilicon 36 is deposited. This step eliminates a standard masking step and allows the emitter polysilicon 36 to be self-aligned to the emitter region 34 and substantially coextensive with and not extending laterally beyond the emitter contact 38 structure. As can be seen in FIG. 4, the top surface of the emitter polysilicon 36 is removed to a point where it is aligned with or slightly below the top edge of the base-emitter spacers. This insures isolation from the base polysilicon. This etch-back step eliminates standard patterning and etch steps typically used to align the emitter contact structure with emitter polysilicon.

The etch back step is unpatterned, and etches through the emitter polysilicon layer 36. The IPD layer 40 can also be etched back in an etch chemistry preferably selective against the spacer material (such as silicon nitride) and polysilicon, so as to stop on the top surface of the base polysilicon layer 32 without causing extensive damage thereto. The structure at this point is shown in FIG. 4. Contact by subsequent conductive layers, such as first metal lines (not shown), to the emitter polysilicon 36 in the emitter contact 38 can be made by forming a contact aperture in subsequently deposited dielectric material over the emitter polysilicon 36. This structure allows a subsequent conductive layer to contact the emitter polysilicon 36.

In the inventive structure and associated method, the emitter polysilicon 36 does not overlap the underlying base polysilicon layer 32. Since the emitter polysilicon 36 no longer overlaps the base link-up polysilicon layer 32, more of the base polysilicon is exposed for silicidation. In addition, the IPD 40 thickness can be reduced. Since there is no overlap of the emitter 36 and base 32 polysilicon layers, there is no need for the IPD 40 to electrically isolate them. The IPD 40 simply functions as a separator and an etch stop. Overall, the topology of the emitter contact structure 38 is improved also to create lesser topographical problems in subsequent steps of the multi-layer process. The structure obtained at this point can be further fabricated into a functioning integrated circuit with known processing methods.

In known emitter contact fabrication processes, after the deposition of the emitter polysilicon, the emitter polysilicon and IPD are patterned using masking and etching steps. The masking and etching steps cause the remaining emitter polysilicon pattern to overlap the P+ polysilicon base layer to some extent. This overlapping structure limits the formation of silicide on the overlapped base P+ polysilicon, which in turn increases base contact resistance. These limitations of know processes are eliminated in the structure and process of the present invention.

While the invention has been particularly shown and described with reference to a preferred embodiment thereof, it will be understood by those skilled in the art that various other changes in the form and details may be made without departing from the spirit and scope of the invention.

A presently preferred embodiment of the present invention and many of its improvements have been described with a degree of particularity. It should be understood that this description has been made by way of example, and that the invention is defined by the scope of the following claims.

We claim:

1. An emitter contact for a bipolar junction transistor comprising:
a silicon substrate having a collector region, a base region within said collector region, and an emitter region within said base region;
a base polysilicon layer positioned on said silicon substrate in contact with said base region and defining an aperture with side walls exposing said base and emitter regions of said silicon substrate;
a spacer extending upwardly from said silicon substrate and formed to cover said side walls, said spacer covering said base region and partially covering said emitter region; and
an emitter polysilicon layer positioned entirely within said aperture in engagement with said emitter region, said spacer and said substrate.

2. An emitter contact as defined in claim 1, wherein:
said spacer defines a top edge and said emitter polysilicon defines a top surface; and
said top surface of said emitter polysilicon is in alignment with said top edge of said spacer.

3. An emitter contact as defined in claim 1, wherein:
said spacer defines a top edge and said emitter polysilicon defines a top surface; and
said top surface of said emitter polysilicon is below said top edge of said spacer.

4. An emitter contact as defined in claim 1, wherein:
said base polysilicon and said emitter polysilicon each have silicided top surfaces.

5. An emitter contact as defined in claim 1, wherein said emitter polysilicon and said base polysilicon are separated only by said spacer.

6. An emitter contact as defined in claim 1, wherein said spacer is silicon nitride.

7. An emitter contact as defined in claim 1, wherein:
said emitter polysilicon is doped with a dopant material; and
said emitter region is formed by the diffusion of said dopant material from said emitter polysilicon.

8. An emitter contact as defined in claim 1, wherein:
said emitter polysilicon is laterally contained within said spacer.

9. An emitter contact as defined in claim 1, wherein said emitter polysilicon layer is 2000 to 4000 Å.

10. An emitter contact as defined in claim 1, wherein said emitter polysilicon layer is doped to a level of up to 1E21 atoms per cubic centimeter.

11. An emitter contact for a bipolar junction transistor comprising:
a silicon substrate having a collector region, a base region within said collector region, and an emitter region within said base region;
a base polysilicon layer positioned on said silicon substrate in contact with said base region and defining an aperture with side walls exposing said base and emitter regions of said silicon substrate;
a spacer extending upwardly from said silicon substrate and formed to cover said side walls, said spacer covering said base region and partially covering said emitter region of said silicon substrate; and
an emitter polysilicon layer positioned in said aperture to form a plug in engagement with said emitter region and said spacer of said substrate without overlapping said base polysilicon.

12. A method for forming an emitter contact for a bipolar junction transistor comprising the steps of:
providing a silicon substrate having a collector region, a base region within said collector region, and an emitter region within said base region;
depositing a base polysilicon layer on said silicon substrate in contact with said base region, and defining an aperture with side walls exposing said base and emitter regions of said silicon substrate;
forming a spacer extending upwardly from said silicon substrate and to cover said side walls, said spacer covering said base region and partially covering said emitter region; and
forming an emitter polysilicon layer positioned within said aperture in engagement with said emitter region, said spacer and said substrate.

13. A method as defined in claim 12, wherein:
said step of depositing a base polysilicon layer further includes the steps of:
depositing a layer of oxide onto said layer of base polysilicon; and
forming said aperture through both of said layers of base polysilicon and oxide.

14. A method as defined in claim 13, wherein:
said step of forming an emitter polysilicon layer further includes the steps of:
depositing a layer of emitter polysilicon onto said oxide and into said aperture; and
etching back said layer of emitter polysilicon to stop on a top surface of said oxide layer.

15. A method as defined in claim 14, further comprising the step of etching back said layer of oxide to stop on a top surface of said base polysilicon layer.

16. A method as defined in claim 12, wherein the step of depositing the emitter polysilicon further includes the steps of:
in situ doping the emitter polysilicon up to a level of 1E21 atoms per cubic centimeter with a dopant material; and
performing a rapid thermal anneal to diffuse the dopant material.
